(19) United States
(12) Patent Application Publication
(10) Pub. No.: US 2016/0102401 A1
(43) Pub. Date: Apr. 14, 2016

(54) VAPOR PHASE GROWTH APPARATUS AND VAPOR PHASE GROWTH METHOD

(71) Applicant: NuFlare Technology, Inc., Kanagawa (JP)

(72) Inventors: Hideshi TAKAHASHI, Yokohama (JP); Yuusuke SATO, Tokyo (JP)

(21) Appl. No.: 14/877,040

(22) Filed: Oct. 7, 2015

(30) Foreign Application Priority Data
Oct. 9, 2014 (JP) 2014-208439

(51) Int. Cl. C23C 16/455; H01L 21/02

(52) U.S. Cl. CPC C23C 16/45561; C23C 16/45565; C23C 16/45512; H01L 21/0254; H01L 21/0262

(57) ABSTRACT

A vapor phase growth apparatus includes a reaction chamber, a shower plate provided at an upper part of the reaction chamber and having a first gas ejection hole and a second gas ejection hole formed in a surface thereof close to the reaction chamber, a first gas supply path connected to the first gas ejection hole and supplying a first process gas including a group III element to the reaction chamber, a second gas supply path connected to the second gas ejection hole and supplying a second process gas including a group V element to the reaction chamber, a first connection path connecting the first gas supply path and the second gas supply path, and a first control unit controlling the passage and stop of gas through the first connection path.

### CROSS-REFERENCE TO RELATED APPLICATION

This application is based upon and claims the benefit of priority from Japanese Patent Applications No. 2014-208439, filed on Oct. 9, 2014, the entire contents of which are incorporated herein by reference.

### FIELD OF THE INVENTION

The present invention relates to a vapor phase growth apparatus and a vapor phase growth method of performing film formation by supplying gases.

### BACKGROUND OF THE INVENTION

As a method of forming a high quality semiconductor film, there is an epitaxial growth technique of forming a single crystal film on a substrate such as a wafer by vapor phase growth. In a vapor phase growth apparatus using the epitaxial growth technique, a wafer is mounted on a support unit in a reaction chamber which is maintained in a normal pressure or a reduced pressure. Next, while heating the wafer, a process gas such as a source gas which is a raw material for film, formation is supplied from, for example, a shower plate at an upper portion of the reaction chamber to a surface of the wafer. Thermal reaction or the like of the source gas occurs on the surface of the wafer, so that a single crystal film is formed on the surface of the wafer in an epitaxial manner (Japanese Patent No. 4864057).

In recent years, as a material for a light emitting device or a power device, a GaN (gallium nitride)-based semiconductor device has attracted attention. As an epitaxial growth technique of forming a GaN-based semiconductor film, there is an organic metal vapor phase growth method (MOCVD method). In the organic metal vapor phase growth method, for example, organic metal such as trimethyl gallium (TMG), trimethyl indium (TMI), and trimethyl aluminum (TMA) or ammonia (NH₃) or the like is used as a source gas.

In some cases, different types of films are formed by a MOCVD method in a light emitting device or a power device.

When different types of films are formed, it is preferable to control the deposition conditions of each film such that deposition characteristics, such as a growth speed, the property of a film, and the uniformity of the thickness of a film, are appropriate.

### SUMMARY OF THE INVENTION

A vapor phase growth apparatus according to an aspect of the invention includes: a reaction chamber; a shower pate that is provided at an upper part of the reaction chamber and has a first gas ejection hole and a second gas ejection hole formed in a surface thereof close to the reaction chamber; a first gas supply path that is connected to the first gas ejection hole and supplies a first process gas including a group III element to the reaction chamber; a second gas supply path that is connected to the second gas ejection hole and supplies a second process gas including a group V element to the reaction chamber; a first connection path that connects the first gas supply path and the second gas supply path; and a first control unit that controls the passage and stop of gas through the first connection path.

A vapor phase growth method according to another aspect of the invention includes: loading a substrate to a reaction chamber; separately supplying gas including a group III element and gas including a group V element to the reaction chamber before the gases are introduced into the reaction chamber to form a first semiconductor film on the substrate; and mixing the gas including the group III element and the gas including the group V element before the gases are introduced into the reaction chamber and supplying the mixed gas to the reaction chamber to form a second semiconductor film on the substrate. The first semiconductor film and the second semiconductor film are continuously formed, without taking out the substrate from the reaction chamber.

### BRIEF DESCRIPTION OF THE DRAWINGS

FIG. 1 is a diagram illustrating the structure of a vapor phase growth apparatus according to a first embodiment;

FIG. 2 is a cross-sectional view schematically illustrating a main portion of a vapor phase growth apparatus according to a first embodiment;

FIG. 3 is a plan view schematically illustrating a shower plate according to the first embodiment;

FIG. 4 is a diagram illustrating the structure of a vapor phase growth apparatus according to a second embodiment;

FIG. 5 is a diagram illustrating the structure of a vapor phase growth apparatus according to a third embodiment;

FIG. 6 is a diagram illustrating the structure of a vapor phase growth apparatus according to a fourth embodiment; and

FIG. 7 is a diagram illustrating the structure of a vapor phase growth apparatus according to a fifth embodiment.

### DETAILED DESCRIPTION OF THE EMBODIMENTS

Hereinafter, embodiments of the invention will be described with reference to the drawings.

In addition, in this specification, in the state where a vapor phase growth apparatus is installed so as to enable film formation, the direction of gravity is defined as a “down” direction, and the opposite direction thereof is defined as an “up” direction. Therefore, the term “lower portion” denotes a position in the direction of gravity with respect to the reference, and the term “under” denotes the direction of gravity with respect to the reference. In addition, the term “upper portion” denotes a position in the opposite direction of the direction of gravity with respect to the reference, and the term “above” denotes the opposite direction of the direction of gravity with respect to the reference. In addition, the term “vertical direction” denotes the direction of gravity.

In the specification, “process gas” is a general term of gas used to form a film on a substrate. The concept of the “process gas” includes, for example, source gas, carrier gas, diluent gas, separation gas, compensation gas, and bubbling gas.

In addition, in this specification, the “separation gas” is a process gas which is introduced into a reaction chamber of a vapor phase growth apparatus and a general term for gases separating process gases of plural source gases.

### First Embodiment

A vapor phase growth apparatus according to this embodiment includes: a reaction chamber; a shower plate that is provided at an upper part of the reaction chamber and has a first gas election hole and a second gas election hole formed in a surface thereof close to the reaction chamber; a first gas supply path that is connected to the first gas ejection hole and supplies a first process gas including a group III element to the reaction chamber; a second gas supply path that is connected to the second gas ejection hole and supplies a second process gas including a group V element to the reaction chamber; a first connection path that connects the first gas supply path and the second gas supply path; and a first control unit that controls the passage and stop of gas through the first connection path.

In addition, a vapor phase growth method according to this embodiment includes: loading a substrate to a reaction chamber; separately supplying gas including a group III element and gas including a group V element to the reaction chamber before the gases are introduced into the reaction chamber to form a first semiconductor film on the substrate; and mixing the gas including the group III element and the gas including the group V element before the gases are introduced into the reaction chamber and supplying the mixed gas to the reaction chamber to form a second semiconductor film on the substrate. The first semiconductor film and the second semiconductor film are continuously formed, without taking out the substrate from the reaction chamber.

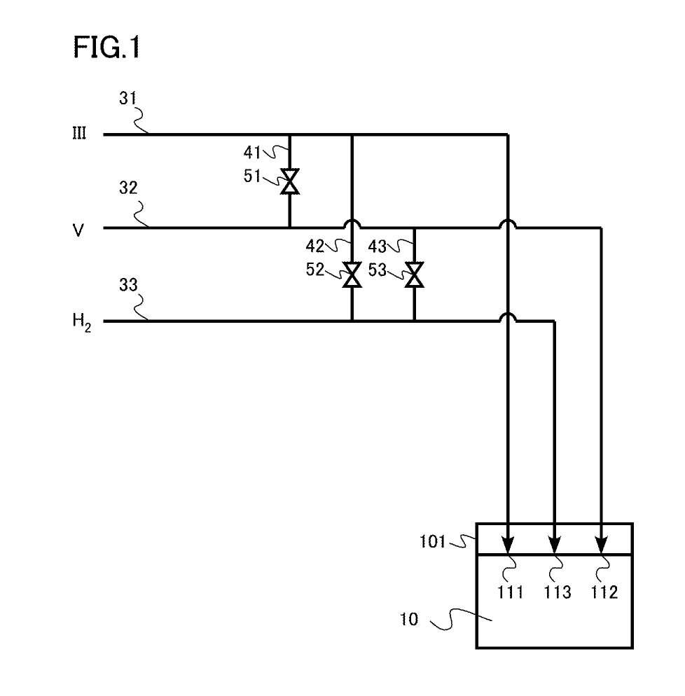

FIG. 1 is a diagram illustrating the structure of a vapor phase growth apparatus according to this embodiment. The vapor phase growth apparatus according to this embodiment is a vertical single-wafer-type epitaxial growth apparatus that uses a metal organic chemical vapor deposition (MOCVD) method. The epitaxial growth apparatus according to this embodiment forms a group III-V nitride-based semiconductor single-crystal film, such as a GaN (gallium nitride) film, an AlN (aluminum nitride) film, an AlGaN (aluminum gallium nitride) film, or an InGaN (indium gallium nitride) film.

The vapor phase growth apparatus includes a reaction chamber 10 in which a film is formed on a substrate such as a wafer. Then, the vapor phase growth apparatus includes a shower plate 101 that is provided at an upper part of the reaction chamber 10. A first gas ejection hole 111, a second gas ejection hole 112, and a third gas ejection hole 113 are provided in a surface of the shower plate 101 close to the reaction chamber 10.

The vapor phase growth apparatus includes a first gas supply path 31 that is connected to the first gas ejection hole 111 and supplies a first process gas including a group III element to the reaction chamber 10. In addition, the vapor phase growth apparatus includes a second gas supply path 32 that is connected to the second gas ejection hole 112 and supplies a second process gas including a group V element to the reaction chamber 10. The vapor phase growth apparatus further includes a third gas supply path 33 that is connected to the third gas ejection hole 113 and supplies a third process gas including hydrogen gas or inert gas to the reaction chamber 10.

The first gas supply path 31 supplies the first process gas including carrier gas and organic metal of a group III element to the reaction chamber 10. The first process gas includes a group III element when a group III-V semiconductor film is formed on the wafer. The carrier gas is, for example, hydrogen gas.

The group III element is, for example, gallium (Ga), aluminum (Al), or indium (In). The organic metal is, for example, trimethylgallium (TMG), trimethylaluminum (TMA), or trimethylindium (TNT).

The second gas supply path 32 supplies the second process gas including a group V element to the reaction chamber 10. The second process gas is a source gas of nitrogen (N), which is a group V element, when a group III-V semiconductor film is formed on the wafer. The second process gas includes, for example, ammonia (NH₃).

The third gas supply path 33 supplies the third process gas including hydrogen as or inert gas to the reaction chamber 10. The third process gas is a so-called separation gas and is ejected between the first process gas and the second process gas when the first process gas and the second process gas are ejected into the reaction chamber 10. The third process gas prevents the reaction between the first process gas and the second process gas immediately after the first process gas and the second process gas are ejected. Therefore, deposition characteristics are improved.

The vapor phase growth apparatus includes a first connection path 41 that connects the first gas supply path 31 and the second gas supply path 32. In addition, the vapor phase growth apparatus includes a first control unit 51 that is provided in the first connection path 41 and controls the passage and stop of gas through the first connection path 41. The first control unit 51 is, for example, a valve.

The vapor phase growth apparatus includes a second connection path 42 that is provided closer to the reaction chamber 10 than the first connection path 41 and connects the first gas supply path 31 and the third gas supply pa 33. The vapor phase growth apparatus further includes a second control unit 52 that is provided in the second connection path 42 and controls the passage and stop of gas through the second connection path 42. The second control unit 52 is, for example, a valve.

The vapor phase growth apparatus further includes a third connection path 43 that is provided closer to the reaction chamber 10 than the first connection path 41 and connects the second gas supply path 32 and the third gas supply path 33. The vapor phase growth apparatus further includes a third control unit 53 that is provided in the third connection path 43 and controls the passage and stop of gas through the third connection path 43. The third control unit 53 is, for example, a valve.

The connection position between the second connection path 42 and the first gas supply path 31 is between the reaction chamber 10 and the connection position between the first connection path 41 and the first gas supply path 31. The connection position between the third connection path 43 and the second gas supply path 32 is between the reaction chamber 10 and the connection position between the first connection path 41 and the second gas supply path 32. The connection position between the third connection path 43 and the third gas supply path 33 is between the reaction chamber 10 and the connection position between the second connection path 42 and the third gas supply path 33.

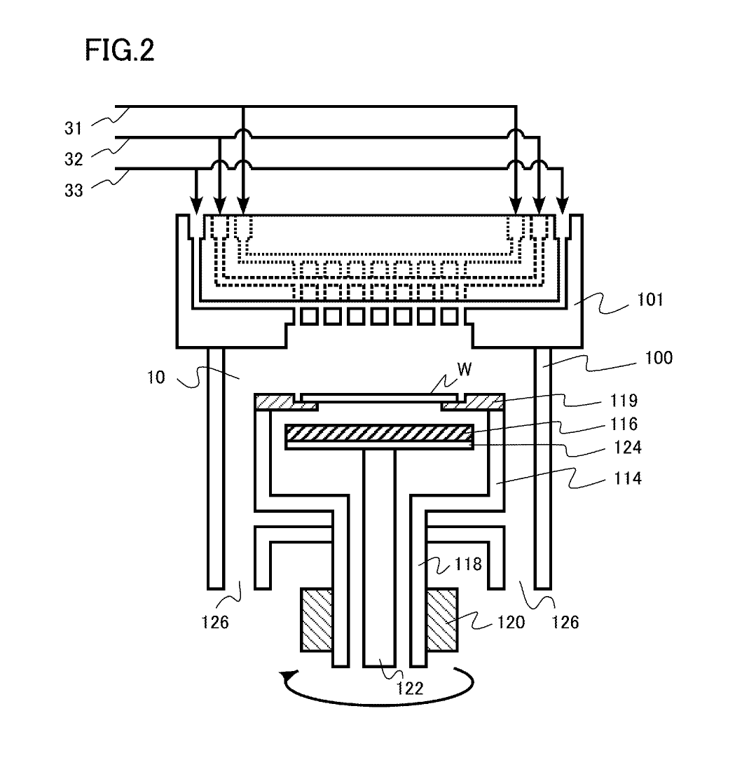

FIG. 2 is a cross-sectional view schematically illustrating a main portion of the vapor phase growth apparatus according to this embodiment. As illustrated in FIG. 2, the reaction chamber 10 according to this embodiment includes, for example, a wall surface 100 of a stainless cylindrical hollow body. The reaction chamber 10 includes the shower plate 101 that is provided in the upper part of the reaction chamber 10 and supplies the process gas into the reaction chamber 10.

The reaction chamber 10 includes a support portion 119 which is provided below the shower plate 101 in the reaction chamber 10 and on which a semiconductor wafer (substrate) W can be placed. The support portion 119 is, for example, an annular holder that has an opening formed at the center thereof or a susceptor that comes into contact with the substantially entire rear surface of the semiconductor wafer W.

The first gas supply path 31, the second gas supply path 32, and the third gas supply path 33 are connected to the shower plate 101. The first gas ejection hole 111, the second gas ejection hole 112, and the third gas ejection hole 113 for respectively ejecting the first, second, and third process gases supplied from the first gas supply path 31, the second gas supply path 32, and the third gas supply path 33 into the reaction chamber 10 are provided in the surface of the shower plate 101 close to the reaction chamber 10.

A rotating unit 114 which rotates with the support portion 119 arranged on the upper surface thereof and a heater which serves as a heating unit 116 for heating the wafer W placed on the support portion 119 are provided below the support portion 119. In the rotating unit 114, a rotating shaft 118 is connected to a rotating mechanism 120 that is provided on the lower side. The rotating mechanism 120 can rotate the semiconductor wafer W about the center of the semiconductor wafer W at a speed that is, for example, equal to or greater than 50 rpm and equal to or less than 3000 rpm.

It is preferable that the diameter of the cylindrical rotating unit 114 be substantially equal to the outside diameter of the support portion 119. The rotating shaft 118 is provided at the bottom of the reaction chamber 10 so as be rotated through a vacuum seal member.

The heating unit 116 is provided so as to be fixed to a support stand 124 fixed to a support shaft 122 which passes through the rotating shaft 118. Power is supplied to the heating unit 116 by a current introduction terminal and an electrode (not illustrated) The support stand 124 is provided with, for example, a push-up pin (not illustrated) that is used to attach or detach the semiconductor wafer W to or from the support portion 119.

A gas discharge portion 126 that discharges a reaction product obtained by the reaction of a source gas on the surface of the semiconductor wafer W and a residual gas in the reaction chamber 10 to the outside of the reaction chamber 10 is provided at the bottom of the reaction chamber 10.

In the reaction chamber 10 illustrated in FIG. 2, a wafer inlet and a gate valve (not illustrated) through which the semiconductor wafer W passes are provided in the side wall of the reaction chamber 10. The semiconductor wafer W can be transferred by a handling arm between a load lock chamber (not illustrated) and the reaction chamber 10 which are connected by the gate valve. For example, the handling arm in which a hand portion provided at the leading end is made of synthetic quart can be inserted into a space between the shower plate 101 and the support portion 119.

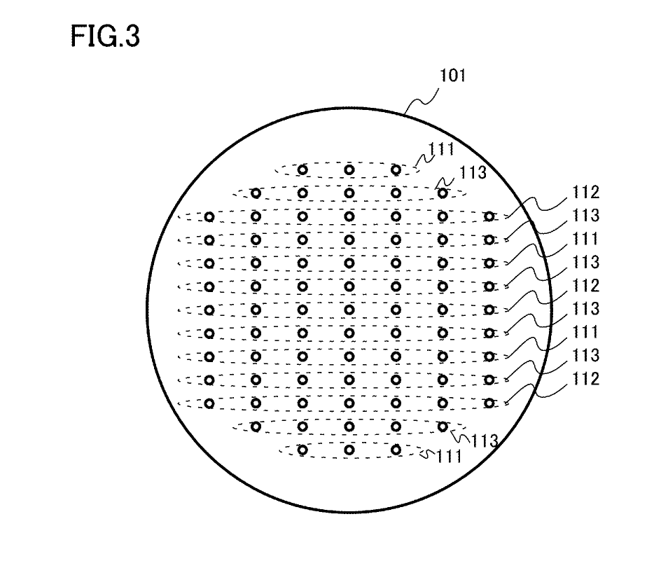

FIG. 3 is a plan view schematically illustrating the shower plate according to this embodiment. FIG. 3 is a plan view illustrating the shower plate 101 as viewed from the reaction chamber 10.

The shower plate 101 has, for example, a plate shape with a predetermined thickness. The shower plate 101 is made of a metal material such as stainless steel or aluminum alloy.

The first gas ejection hole 111, the second gas ejection hole 112, and the third gas ejection hole 113 are provided in the surface of the shower plate 101 close to the reaction chamber 10. The third gas ejection hole 113 is arranged between the first gas ejection hole 111 and the second gas ejection hole 112.

For example, the first process gas including a group III element is supplied from the first gas ejection hole 111 to the reaction chamber 10. For example, the second process gas including a group V element is supplied from the second gas ejection hole 112 to the reaction chamber 10. For example, the third process gas including a hydrogen gas or inert gas is supplied from third gas ejection hole 113 to the reaction chamber 10.

A vapor phase growth method according to this embodiment is performed using the epitaxial growth apparatus illustrated in FIGS. 1 and 2. Next, an example in which an aluminum nitride (AlN) film, serving as a first semiconductor film, and a gallium nitride (GaN) film serving as a second semiconductor film are continuously formed by the vapor phase growth method according to this embodiment will be described.

First, the semiconductor wafer W, which is an example of a substrate, is loaded to the reaction chamber 10.

For example, hydrogen gas is supplied from the first, second, and third gas supply paths 31, 32, and 33 to the reaction chamber 10 and a vacuum pump (not illustrated) is operated to discharge gas in the reaction chamber 10 from a gas discharge portion 126. The semiconductor wafer W is placed on the support portion 119 in the reaction chamber 10, with the reaction chamber 10 controlled at a predetermined pressure.

When the semiconductor wafer W is loaded, for example, the gate valve (not illustrated) of the wafer inlet of the reaction chamber 10 is opened and the semiconductor wafer W in the load lock chamber is loaded to the reaction chamber 10 by the handling arm. Then, the semiconductor wafer W is placed on the support portion 119 through, for example, the push-up pin (not illustrated). The handling arm is returned to the load lock chamber and the gate valve is closed.

Here, the semiconductor wafer W placed on the support portion 119 is preliminarily heated to a predetermined temperature by the heating unit 116. Then, the heating power of the heating unit 116 increases and the semiconductor wafer W is heated to a predetermined temperature, for example, a deposition temperature of about 1100° C.

Then, TMA (gas including a group III element) having hydrogen gas as the carrier gas is supplied to the first gas supply path 31. In addition, gas including ammonia (gas including a group V element) is supplied to the second gas supply path 32. Hydrogen gas is supplied as the separation gas to the third gas supply path 33.

When the AlN film is formed, the first control unit 51 blocks the flow of gas through the first connection path 41. In addition, the second control unit 52 blocks the flow of gas through the second connection path 42. The third control unit 53 blocks the flow of gas through the third connection path 43.

Then, the gas including TMA, the gas including ammonia, and the separation gas are separately supplied to the reaction chamber 10 before it is introduced into the reaction chamber 10. The gas including TMA, the gas including ammonia, and the hydrogen gas are independently supplied from the first gas ejection hole 111, the second gas ejection hole 112, and the third gas ejection hole 113 to the reaction chamber 10, respectively.

In this way, the AlN film is epitaxially grown on the surface of the semiconductor wafer W. When the growth of the AlN film is completed, the flow of TMA to the first gas supply path 31 is blocked. In this way, the growth of an AlN single-crystal film is completed.

Then, a GaN film is continuously formed on the AlN film, without taking out the semiconductor wafer W from the reaction chamber 10.

The TMG (gas including a group III element) having hydrogen gas as the carrier gas is supplied to the first gas supply path 31. In addition, gas including ammonia (gas including a group V element) is supplied to the second gas supply path 32. The supply of hydrogen gas to the third gas supply path 33 is stopped.

When the GaN film is formed, the first control unit 51 performs control such that gas flows through the first connection path 41. The second control unit 52 performs control such that gas flows through the second connection path 42. The third control unit 53 performs control such that gas flows through the third connection path 43.

Then, gas including TMG and gas including ammonia are mixed before they are introduced into the reaction chamber 10 and the mixed gas is supplied to the reaction chamber 10. The mixed gas is also supplied to the third gas supply path 33 through the second connection path 42 and the third connection path 43. Therefore, the mixed gas including both TMG and ammonia is supplied from the first gas ejection hole 111, the second gas ejection hole 112, and the third gas ejection hole 113 to the reaction chamber 10.

In this way, the GaN film is epitaxially grown on the AlN film of the semiconductor wafer W. When the growth of the GaN film is completed, the flow of TMG to the first gas supply path 31 is blocked. In this way, the growth of a GaN single-crystal film is completed.

Then, the heating power of the heating unit 116 is decreased to reduce the temperature of the semiconductor wafer W. After the temperature of the semiconductor wafer W is reduced to a predetermined temperature, the supply of ammonia from the second gas supply path 32 to the reaction chamber 10 is stopped.

When the formation of the film is completed, hydrogen gas supplied to the reaction chamber 10 through the first gas supply path 31. In addition, hydrogen gas is supplied to the reaction chamber 10 through the second gas supply path 32.

Here, for example, the rotation of the rotating unit 114 is stopped and the heating power of the heating unit 116 is adjusted to reduce the transfer temperature, with the semiconductor wafer W having the single-crystal film formed thereon being placed on the support portion 119.

Then, for example, the semiconductor wafer W is detached from the support portion 119 by the push-up pin Then, the gate valve is opened again and the handling arm is inserted between the shower plate 101 and the support portion 119. Then, the semiconductor wafer W is placed on the handling arm. Then, the handling arm having the semiconductor wafer W placed thereon returns to the load lock chamber.

In this way, one firm formation process for the semiconductor wafer W is completed. For example, films may be formed on another semiconductor wafer W by the same process sequence as described above.

Optimal deposition conditions vary depending on the type of group III-V semiconductor film. For example, in the case of an AlN film, it is preferable that TMA and ammonia be separately introduced from the shower plate 101 to the reaction chamber 10, in order to improve surface morphology or crystallinity. In contrast, in the case of a semiconductor film including Ga, such as a GaN film, it is preferable that a mixed gas of TMG and ammonia be introduced from the shower plate 101 to the reaction chamber 10, in order to increase a growth speed while ensuring good film characteristics.

In this embodiment, the vapor phase growth apparatus includes the first connection path 41 and the first control unit 51. Therefore, it is possible to separately supply gas including a group III element and gas including a group V element from the shower plate 101 to the reaction chamber 10 or it is possible to supply a mixture of the gas including a group III element and the gas including a group V element from the shower plate 101 to the reaction chamber 10. As a result, when different types of films are formed, it is possible to control the deposition conditions of each film such that deposition characteristics are appropriate.

In addition, the vapor phase growth apparatus includes the third gas supply path 33 for supplying the separation gas It is possible to improve deposition characteristics when the gas including a group III element and the gas including a group V element are separately supplied to the reaction chamber 10. Furthermore, the vapor phase growth apparatus includes the second control unit 52, the second connection path 42, the third control unit 53, and the third connection path 43. Therefore, when a mixture of the gas including a group III element and the gas including a group V element is supplied to the reaction chamber 10, the mixed gas can also be supplied from the third gas election hole 113. As a result, deposition characteristics including the uniformity of the thickness of a film are improved.

According to the vapor phase growth method of this embodiment, when different types of films are continuously formed in the same reaction chamber 10, deposition conditions are control led such that deposition characteristics are appropriate. Therefore, it is possible to manufacture a substrate including a high-quality semiconductor stacked film with high throughput.

In the above-described embodiment, the vapor phase growth apparatus includes the third gas supply path 33. However, the third gas supply path 33 may be omitted. In addition, when the vapor phase growth apparatus includes the third gas supply path 33, the second control unit 52, the second connection path 42, the third control unit 53, and the third connection path 43 may be omitted.

In the vapor phase growth method according to the above-described embodiment, the gas including a group III element and the gas including a group V element are separately supplied to the reaction chamber before they are introduced into the reaction chamber to form the first semiconductor film on the substrate. Then, a mixture of the gas including a group III element and the gas including a group V element is supplied to the reaction chamber before the gas including a group III element and the gas including a group V element are introduced into the reaction chamber to form the second semiconductor film. However, the processes are not necessarily limited to the above-mentioned order. For example, the following method may be used: a mixture of the gas including a group III element and the gas including a group V element is supplied to the reaction chamber before the gas including a group III element and the gas including a group V element are introduced into the reaction chamber to form the second semiconductor film; and the gas including a group III element and the gas including a group V element are separately supplied to the reaction chamber before they are introduced into the reaction chamber to form the first semiconductor film on the substrate.

### Second Embodiment

A vapor phase growth apparatus according to this embodiment is similar to the vapor phase growth apparatus according to the first embodiment except that the second connection path 42 and the third connection path 43 are provided so as to be opposite to the reaction chamber 10 with the first connection path 41 interposed therebetween. Therefore, the description of the same structures as those in the first embodiment will not be repeated.

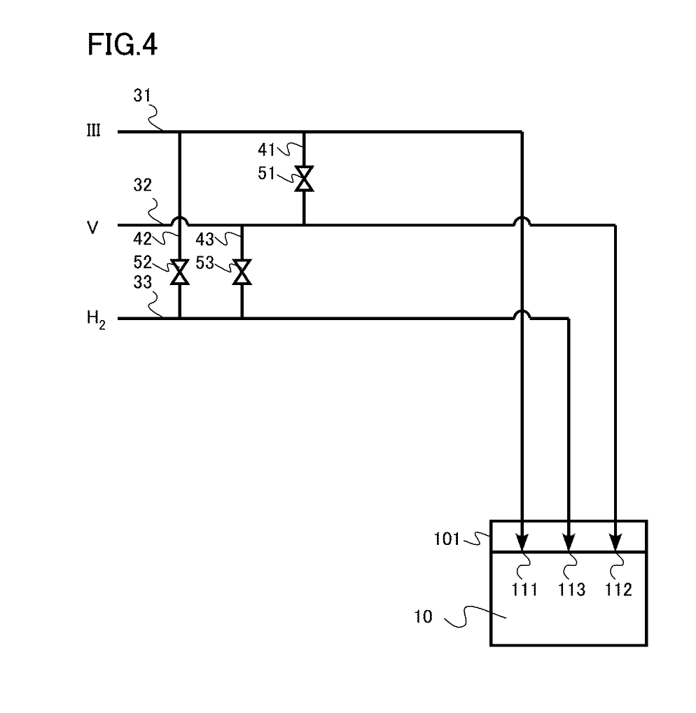

FIG. 4 is a diagram illustrating the structure of the vapor phase growth apparatus according to this embodiment. The second connection path 42 is provided so as to be opposite to the reaction chamber 10, with the first connection path 41 interposed therebetween, and connects the first gas supply path 31 and the third gas supply path 33. The third connection path 43 is provided so as to be opposite to the reaction chamber 10, with the first connection path 41 interposed therebetween, and connects the second gas supply path 32 and the third gas supply path 33.

The connection position between the first connection path 41 and the first gas supply path 31 is between the reaction chamber 10 and the connection position between the second connection path 42 and the first gas supply path 31. The connection position between the first connection path 41 and the second gas supply path 32 is between the reaction chamber 10 and the connection position between the third connection path 43 and the second gas supply path 32. The connection position between the third connection path 43 and the third gas supply path 33 is between the reaction chamber 10 and the connection position between the second connection path 42 and the third gas supply path 33.

In the vapor phase growth apparatus according to this embodiment, when different types of films are formed, it is also possible to control the deposition conditions of each film such that deposition characteristics are appropriate.

### Third Embodiment

A vapor phase growth apparatus according to this embodiment is similarly the vapor phase growth apparatus according to the first embodiment except that the third connection path 43 for connecting the second gas supply path 32 and the third gas supply path 33 is not provided. Therefore, the description of the same structures as those in the first embodiment will not be repeated.

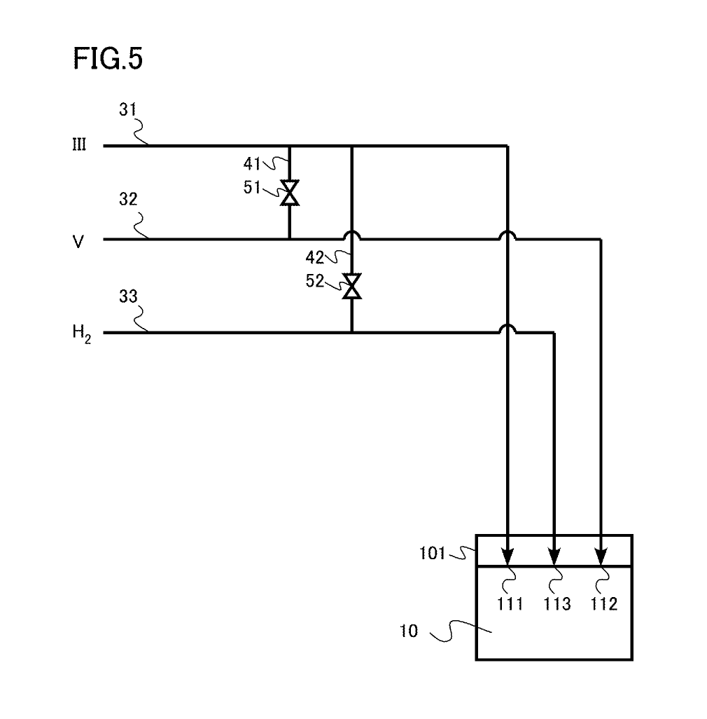

FIG. 5 is a diagram illustrating the structure of the vapor phase growth apparatus according to this embodiment. The vapor phase growth apparatus includes the second connection path 42 that is provided closer to the reaction chamber 10 than the first connection path 41 and connects the first gas supply path 31 and the third gas supply path 33. In addition, the vapor phase growth apparatus includes the second control unit 52 that is provided in the second connection path 42 and controls the passage and stop of gas through the second connection path 42. The second control unit 52 is, for example, a valve.

In the vapor phase growth apparatus according to this embodiment, when different types of films are formed, it is also possible to control the deposition conditions of each film such that deposition characteristics are appropriate.

### Fourth Embodiment

A vapor phase growth apparatus according to this embodiment is similar to the vapor phase growth apparatus according to the first embodiment except that the second connection path 42 for connecting the first gas supply path 31 and the third gas supply path 33 is not provided. Therefore, the description of the same structures as those in the first embodiment will not be repeated.

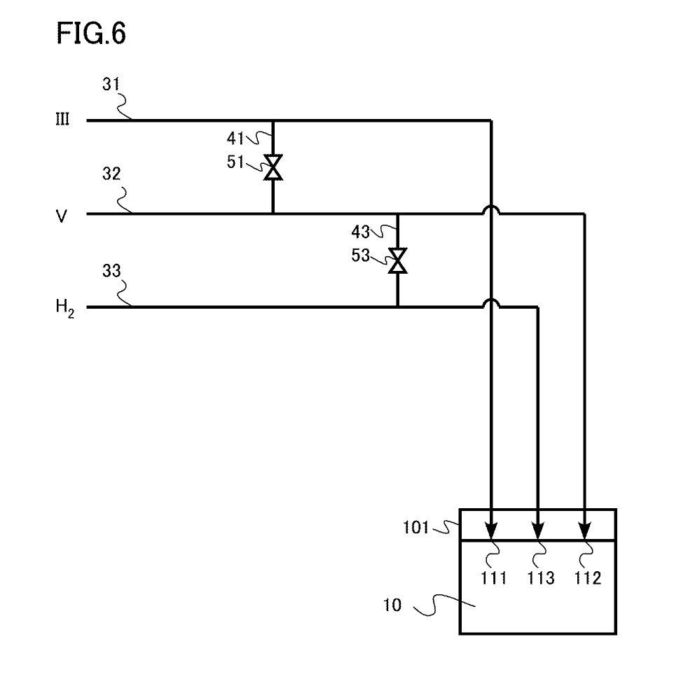

FIG. 6 is a diagram illustrating the structure of the vapor phase growth apparatus according to this embodiment. The vapor phase growth apparatus includes the third connection path (second connection path) 43 that is provided closer to the reaction chamber 10 than the first connection path 41 and connects the second gas supply path 32 and the third gas supply path 33. In addition, the vapor phase growth apparatus includes the third control unit (second control unit) 53 that is provided in the third connection path 43 and controls the passage and stop of gas through the third connection path 43. The third control unit 53 is, for example, a valve.

In the vapor phase growth apparatus according to this embodiment, when different types of films are formed, it is also possible to control the deposition conditions of each film such that deposition characteristics are appropriate.

### Fifth Embodiment

A vapor phase growth apparatus according to this embodiment includes a reaction chamber, a shower plate that is provided in an upper part of the reaction chamber and has a first gas erection hole and a second gas ejection hole formed in a surface thereof close to the reaction chamber, a first gas supply path that is connected to the first gas ejection hole and supplies a first process gas to the reaction chamber, a second gas supply path that is connected to the second gas ejection hole and supplies a second process gas to the reaction chamber, a first source gas supply path that supplies a first source gas including a group III element to the first gas supply path or the second gas supply path, a second source gas supply path that supplies a second source gas including a group V element to the first gas supply path or the second gas supply path, a first connection path that connects the first source gas supply path and the first gas supply path, a second connection path that connects the first source gas supply path and the second gas supply path, a third connection path that connects the second source gas supply path and the first gas supply path, a fourth connection path that connects the second source gas supply path and the second as supply path, a first control unit that controls the passage and stop of gas through the first connection path, a second control unit that controls the passage and stop of gas through the second connection path, a third control unit that controls the passage and stop of gas through the third connection path, and a fourth control unit that controls the passage and stop of gas through the fourth connection path. Hereinafter, the description of the same structures as those in the first embodiment will riot be repeated.

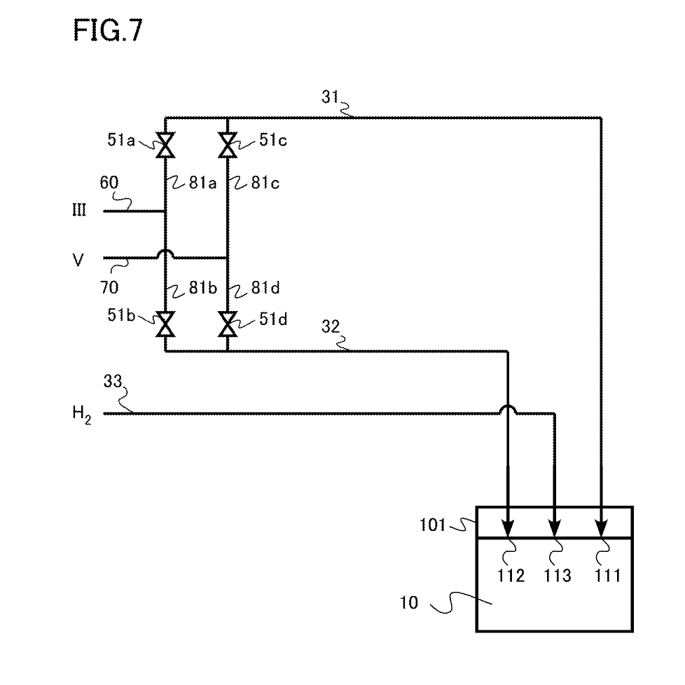

FIG. 7 is a diagram illustrating the structure of the vapor phase growth apparatus according to this embodiment. The vapor phase growth apparatus according to this embodiment includes a reaction chamber 10 and a shower plate 101, similarly to the first embodiment.

The vapor phase growth apparatus includes a first gas supply path 31 that is connected to a first gas ejection hole 111 and supplies a first process gas to the reaction chamber 10 and a second gas supply path 32 that is connected to a second gas ejection hole 112 and supplies a second process gas to the reaction chamber 10. In addition, the vapor phase growth apparatus includes a third gas supply path 33 that is connected to a third gas ejection hole 113 and supplies a third process gas including hydrogen gas or inert gas to the reaction chamber 10.

The vapor phase growth apparatus further includes a first source gas supply path 60 that supplies a first source gas including a group III element to the first gas supply path 31 or the second gas supply path 32 and a second source gas supply path 70 that supplies a second source gas including a group V element to the first gas supply path 31 or the second gas supply path 32.

The first source gas includes, for example, trimethylgallium (TMG) trimethylaluminum (TMA), or trimethylindium (TNT) The second source gas includes, for example, ammonia (NH₃).

The vapor phase growth apparatus further includes a first connection path 81a that connects the first source gas supply path 60 and the first gas supply path 31, a second connection path 81b that connects the first source gas supply path 60 and the second gas supply path 32, a third connection path 81c that connects the second source gas supply path 70 and the first gas supply path 31, and a fourth connection path 81d that connects the second source gas supply path 70 and the second gas supply path 32.

The vapor phase growth apparatus further includes a first control unit 51a that controls the passage and stop of gas through the first connection path 81a, a second control unit 51b that controls the passage and stop of gas through the second connection path 81b, a third control unit 51c that controls the passage and stop of gas through the third connection path 81c, and a fourth control unit 51d that controls the passage and stop of gas through the fourth connection path 81d.

In a vapor phase growth method using the vapor phase growth apparatus according to this embodiment, when an AlN film is formed, TMA (gas including a group III element) having hydrogen gas as carrier gas is supplied as the first source gas to the first source gas supply path 60. In addition, gas including ammonia (gas including a group V element) is supplied as the second source gas to the second source gas supply path 70.

Then, the first control unit 51a is opened and TMA (gas including a group III element) having hydrogen gas as carrier gas is supplied from the first source gas supply path 60 to the first gas supply path 31. In contrast, the second control unit 51b is closed and the supply of the TMA having hydrogen gas as carrier gas to the second gas supply path 32 is cut off. In addition, the fourth control unit 51d is opened and gas including ammonia (gas including a group V element) is supplied from the second source gas supply path 70 to the second gas supply path 32. In contrast, the third control unit 51c is closed and the supply of the gas including ammonia (gas including a group V element) to the first gas supply path 31 is cut off in addition, hydrogen gas is supplied as separation gas to the third gas supply path 33.

In this way, the gas including TMA, the gas including ammonia, and the separation gas are separately supplied to the reaction chamber 10 before they are introduced into the reaction chamber 10. Therefore, the gas including TMA, the gas including ammonia, and the hydrogen gas are independently supplied from the first gas ejection hole Ill, the second gas ejection hole 112, and the third gas ejection hole 113 to the reaction chamber 10, respectively.

When a GaN film is formed, all of the first to fourth control units 51a, 51b, 51c, and 51d are opened. The gas including TMG and the gas including ammonia are mixed before they are introduced into the reaction chamber 10 and the mixed gas is supplied to the first gas supply path 31 and the second gas supply path 32. Therefore, a mixture of the gas including TMA and the gas including ammonia is supplied from the first as ejection hole 111 and the second gas ejection hole 112 to the reaction chamber 10. The hydrogen gas may be supplied to the third gas supply path 33 or the supply of the hydrogen gas to the third gas supply path 33 may be cut off.

In the vapor phase growth apparatus according to this embodiment, when different types of films are formed, it is also possible to control the deposition conditions of each film such that deposition characteristics are appropriate. The provision of four connection paths and four control units makes it possible to stably mix the process gases.

The embodiments of the invention have been described above with reference to examples. The above-described embodiments are illustrative examples and do not limit the invention. In addition, the components according to each embodiment may be appropriately combined with each other.

For example, in the above-described embodiments, the

AlN and GaN (gallium, nitride) single-crystal films are formed. However, for example, the invention can be applied to other group nitride-based semiconductor single-crystal films, such as AlGaN (aluminum gallium nitride) and InGaN (indium gallium nitride) single-crystal films. In addition, the invention can be applied to a group III-V semiconductor such as GaAs.

In the above-described embodiments, hydrogen gas (H₂) is used as the carrier gas and the separation gas. However, inert gas, such as nitrogen gas (N₂), argon gas (Ar), or helium gas (He), or a combination of the gases can be applied.

In the above-described embodiments, the vertical single-wafer-type epitaxial apparatus is used to form films on one wafer. However, the vapor phase growth apparatus is not limited to the single-wafer-type epitaxial apparatus. For example, the invention can be applied a horizontal epitaxial apparatus or a planetary CVD apparatus that simultaneously forms films on a plurality of wafers which revolve on their own axes and around the apparatus.

In the embodiments, although the apparatus components, the manufacturing methods, and the like that are not directly needed to describe the invention are omitted in the description, the apparatus components, the manufacturing methods, and the like that are to be needed may be appropriately selected to be used. All of the vapor phase growth apparatuses and the vapor phase growth methods that include the elements of the invention and can be appropriately modified in design by the ordinarily skilled in the art are included within the scope of the invention. The scope of the invention is defined by the claims and the equivalents thereof.

What is claimed is:

1. A vapor phase growth apparatus comprising:
a reaction chamber;
a shower plate provided at an upper part of the reaction chamber and having a first gas ejection hole and a second gas ejection hole formed in a surface thereof close to the reaction chamber;
a first gas supply path connected to the first gas ejection hole and supplying a first process gas including a group element to the reaction chamber;
a second gas supply path connected to the second gas ejection hole and supplying a second process gas including a group V element to the reaction chamber;
a first connection path connecting the first gas supply path and the second gas supply path; and
a first control unit controlling the passage and stop of gas through the first connection path.

2. The vapor phase growth apparatus according to claim 1, further comprising:
a third gas supply path connected to a third gas ejection hole of the shower plate and supplying a third process gas including hydrogen gas or inert gas to the reaction chamber.

3. The vapor phase growth apparatus according to claim 2, further comprising:
a second connection path connecting the first gas supply path and the third gas supply path;
a third connection path connecting the second gas supply path and the third gas supply path;
a second control unit controlling the passage and stop of gas through the second connection path; and
a third control unit controlling the passage and stop of gas through the third connection path.

4. The vapor phase growth apparatus according to claim 2, further comprising:
a second connection path connecting the first gas supply path and the third gas supply path and/or connecting the second gas supply path and the third gas supply path; and
a second control unit controlling the passage and stop of gas through the second connection path.

5. The vapor phase growth apparatus according to claim 3,
wherein a connection position between the second connection path and the first gas supply path is between the reaction chamber and a connection position between the first connection path and the first gas supply path,
a connection position between the third connection path and the second gas supply path is between the reaction chamber and a connection position between the first connection path and the second gas supply path, and
a connection position between the third connection path and the third gas supply path is between the reaction chamber and a connection position between the second connection path and the third gas supply path.

6. The vapor phase growth apparatus according to claim 2,
wherein a connection position between the first connection path and the first gas supply path is between the reaction chamber and a connection position between the second connection path and the first gas supply path,
a connection position between the first connection path and the second gas supply path is between the reaction chamber and a connection position between the third connection path and the second gas supply path, and
a connection position between the third connection path and the third gas supply path is between the reaction chamber and a connection position between the second connection path and the third gas supply path.

7. The vapor phase growth apparatus according to claim 1,
wherein the group III element is gallium (Ga), aluminum (Al), or indium (In) and the group V element is nitrogen (N).

8. The vapor phase growth apparatus according to claim 1,
wherein the first process gas includes trimethylgallium (TMG), trimethylaluminum (TMA), or trimethylindium (TMT) and the second process gas includes ammonia (NH₃).

9. A vapor phase growth apparatus comprising:
a reaction chamber;
a shower plate provided at an upper part of the reaction chamber and having a first gas ejection hole and a second gas ejection hole formed in a surface thereof close to the reaction chamber;
a first gas supply path connected to the first gas ejection hole and supplying a first process gas to the reaction chamber;
a second gas supply path connected to the second gas ejection hole and supplying a second process gas to the reaction chamber;
a first source gas supply path supplying a first source gas including a group III element to the first gas supply path or the second gas supply path;
a second source gas supply path supplying a second source gas including a group V element to the first gas supply path or the second gas supply path;
a first connection path connecting the first source gas supply path and the first gas supply path;
a second connection path connecting the first source gas supply path and the second gas supply path;
a third connection path connecting the second source gas supply path and the first gas supply path;
a fourth connection path connecting the second source gas supply path and the second gas supply path;
a first control unit controlling the passage and stop of gas through the first connection path;
a second control unit controlling the passage and stop of gas through the second connection path;
a third control unit controlling the passage and stop of gas through the third connection path; and
a fourth control unit controlling the passage and stop of gas through the fourth connection path.

10. The vapor phase growth apparatus according to claim 9, further comprising:
a third gas supply path connected to a third gas ejection hole of the shower plate and supplying a third process gas including hydrogen gas or inert gas to the reaction chamber.

11. The vapor phase growth apparatus according to claim 9,
wherein the group III element is gal gallium (Ga), aluminum (Al), or indium (In) and the group V element is nitrogen (N).

12. The vapor phase growth apparatus according to claim 9,
wherein the first process gas includes trimethylgallium (TMG), trimethylaluminum (TMA), or trimethylindium (TMI) and the second process gas includes ammonia (NH₃).

13. A vapor chase growth method comprising:
loading a substrate to a reaction chamber;
separately supplying gas including a group III element and gas including a group V element to the reaction chamber before the gases are introduced into the reaction chamber to form a first semiconductor film on the substrate; and
mixing the gas including the group III element and the gas including the group V element before the gases are introduced into the reaction chamber and supplying the mixed gas to the reaction chamber to form a second semiconductor film on the substrate, after forming the first semiconductor film without taking out the substrate from the reaction chamber.

14. The vapor phase growth method according to claim 13,
wherein the group III element is gallium (Ga), aluminum (Al), or indium (In) and the group V element is nitrogen (N).

15. The vapor phase growth method according claim 13,
wherein the gas including the group III element includes trimethylgallium (TMG) trimethylaluminum (TMA), or trimethylindium (TMI) and the gas including the group V element includes ammonia (NH₃).
